(19) United States
(12) Patent Application Publication
(10) Pub. No.: US 2016/0045935 A1
(43) Pub. Date: Feb. 18, 2016

(54) CAPACITIVE MICROMACHINED ULTRASONIC TRANSDUCER HAVING NANOPILLAR STRUCTURE AND METHOD OF FABRICATING THE SAME

(71) Applicant: Samsung Electronics Co., Ltd., Suwon-si (KR)

(72) Inventors: Yongseop YOON, Seoul (KR); Sungchan KANG, Hwaseong-si (KR); Seokwhan CHUNG, Hwaseong-si (KR)

(73) Assignee: SAMSUNG ELECTRONICS CO., LTD., Suwon-si, Gyeonggi-do (KR)

(21) Appl. No.: 14/686,459

(22) Filed: Apr. 14, 2015

(30) Foreign Application Priority Data
Aug. 18, 2014 (KR) 10-2014-0106966

(51) Int. Cl. B06B 1/02; B81B 7/00; B81C 1/00

(52) U.S. Cl. CPC B06B 1/0292; B81C 1/00031; B81B 7/008

(57) ABSTRACT

Example embodiments relate to a capacitive micromachined ultrasonic transducer (CMUT) having a nanopillar structure and a method of fabricating the same. The CMUT may include a conductive device substrate, a support defining a plurality of cavities corresponding to elements on the device substrate, a membrane on the support to form the plurality of cavities, an upper electrode on the membrane, and a plurality of nanopillars on at least one of the membrane and the device substrate exposed to the plurality of cavities.

### RELATED APPLICATION

This application claims the benefit of priority from Korean Patent Application No. 10-2014-0106966, filed on Aug. 18, 2014, in the Korean Intellectual Property Office, the disclosure of which is incorporated herein in its entirety by reference.

### BACKGROUND

1. Field

Example embodiments relate to capacitive micromachined ultrasonic transducers (CMUTs) having driving units configured of nanopillar structures and methods of fabricating the same.

2. Description of the Related Art

Micromachined ultrasonic transducers (MUTs) are devices that convert electrical signals into ultrasonic signals or vice versa. These MUTs may be classified into piezoelectric micromachined ultrasonic transducers (PUMTs), capacitive micromachined ultrasonic transducers (CMUTs), and magnetic micromachined ultrasonic transducers (MMUTs) according to conversion methods.

A CMUT includes a driving unit configured of a movable upper electrode (membrane) and a fixed lower electrode. When a voltage is applied between the upper electrode and the lower electrode, electrostatic attraction is generated, and the membrane attached to the upper electrode is pulled down toward the lower electrode. When the applied voltage is removed, the membrane is restored such that a sound pressure is generated. In this case, as the electrostatic attraction is increased, a restoring force is increased and thus the sound pressure is increased.

In order to increase the electrostatic attraction, an area in which the upper electrode and the lower electrode face each other needs to be increased, a driving voltage needs to be increased, or a distance between the upper electrode and the lower electrode needs to be decreased. However, in order to increase the area, the size of the membrane needs to be increased. This causes the size of an ultrasonic transducer to be increased, and a change in sound characteristics, such as a change in frequencies, accompanies this increase in size. Also, when the driving voltage is increased, the size of a power supply unit may be increased and thus, power consumption is increased.

### SUMMARY

Example embodiments relate to capacitive micromachined ultrasonic transducers (CMUTs), whereby nanopillars are formed on at least one of a membrane and a lower electrode so that electrostatic attraction may be increased.

Example embodiments also relate to methods of fabricating the CMUTs.

Additional features will be set forth in part in the description which follows and, in part, will be apparent from the description, or may be learned by practice of some example embodiments.

According to some of the example embodiments, a capacitive micromachined ultrasonic transducer (CMUT) may include a conductive device substrate, a support defining a plurality of cavities corresponding to a plurality of elements on the device substrate, a membrane on the support to form the plurality of cavities, an upper electrode on the membrane, and a plurality of nanopillars on at least one of the membrane and the device substrate exposed to the plurality of cavities.

The plurality of nanopillars may be on a surface of the membrane protruding toward the device substrate.

Protrusion surfaces of the plurality of nanopillars may be on a same plane as the surface of the membrane contacting the support.

Diameters of the plurality of nanopillars may be in a range from 10 nm to 100 nm.

The CMUT may further include an insulating layer on an exposed surface of the plurality of nanopillars.

The plurality of nanopillars may be on a surface of the device substrate protruding toward the membrane.

Protrusion surfaces of the plurality of nanopillars may be on a same plane as the surface of the device substrate contacting the support.

Diameters of the plurality of nanopillars may be in a range from 10 nm to 100 nm.

The CMUT may further include an insulating layer on an exposed surface of the plurality of nanopillars.

The plurality of nanopillars may include a plurality of first nanopillars on a surface of the membrane protruding toward the device substrate, and a plurality of second nanopillars on a surface of the device substrate protruding toward the membrane.

Protrusion surfaces of the plurality of first nanopillars may be on a same plane as the surface of the membrane contacting the support, and protrusion surfaces of the plurality of second nanopillars may be on a same plane as the surface of the device substrate contacting the support.

According to an example embodiment, a method of fabricating a capacitive micromachined ultrasonic transducer (CMUT), the method includes forming an insulating support defining a cavity on a first substrate which is one of a device substrate and a silicon on insulator (SOI) substrate, forming a metal layer on a surface of the first substrate exposed by the support, agglomerating the metal layer into a plurality of metal balls by annealing the metal layer, forming a plurality of nanopillars on the surface of the first substrate by etching the surface of the first substrate by using the plurality of metal balls as a mask, removing the metal balls, forming the cavity between the SOI substrate and the device substrate by bonding the SOI substrate onto the device substrate, removing one silicon layer and a buried oxide layer of the SOI substrate sequentially so as to leave a second silicon layer of the SOI substrate on the support, and forming an upper electrode on the second silicon layer.

The forming of the metal layer may include forming a metal layer having a thickness of 5 nm to 50 nm on the first substrate.

Diameters of the plurality of nanopillars may be in a range from 10 nm to 100 nm.

The device substrate may include low resistivity silicon.

The method may further include forming an insulating layer that covers the plurality of nanopillars.

According to an example embodiment, a method of fabricating a capacitive micromachined ultrasonic transducer (CMUT) includes forming a first support on a device substrate to define a cavity, forming a first metal layer on a surface of the device substrate exposed by the support, forming a plurality of first metal balls on the surface of the device substrate by annealing the first metal layer, forming a plurality of first nanopillars on the surface of the device substrate by etching the surface of the device substrate by using the plurality of metal balls as a mask, removing the metal balls, forming a second support corresponding to the first support on a silicon on insulator (SOI) substrate, forming a second metal layer on a surface of the SOI substrate exposed by the second support, forming a plurality of second metal balls on the surface of the SOI by annealing the second metal layer, forming a plurality of second nanopillars on the surface of the SOI substrate by etching the surface of the SOI substrate by using the plurality of second metal balls as a mask, forming the cavity between the SOI substrate and the device substrate by bonding the SOI substrate onto the device substrate so that the first support and the second support overlap each other, removing one silicon layer and a buried oxide layer of the SOI substrate sequentially so as to leave a second silicon layer of the SOI substrate on the second support, and forming an upper electrode on the second silicon layer.

The forming of the first metal layer and the second metal layer may include forming a metal layer having a thickness of 5 nm to 50 nm on respective substrates.

Diameters of each of the plurality of first nanopillars and the plurality of second nanopillars may be in a range from 10 nm to 100 nm.

The method may further include forming an insulating layer that covers at least one of the plurality of first nanopillars and the plurality of second nanopillars.

### BRIEF DESCRIPTION OF THE DRAWINGS

The foregoing and other features of example embodiments will be apparent from the more particular description of non-limiting embodiments, as illustrated in the accompanying drawings in which like reference characters refer to like parts throughout the different views. The drawings are not necessarily to scale, emphasis instead being placed upon illustrating principles of some example embodiments. In the drawings:

FIG. 1 is a schematic conceptual view of a structure of a capacitive micromachined ultrasonic transducer (CMUT) according to an example embodiment;

FIG. 2 is a schematic bottom view of a CMUT according to an example embodiment;

FIG. 3 is a cross-sectional view taken along a line III-Ill′ of FIG. 2;

FIG. 4 is an enlarged view of a portion A of FIG. 3;

FIGS. 5A through 5L are cross-sectional views illustrating a method of fabricating the CMUT according to an example embodiment;

FIG. 6 is a schematic cross-sectional view of a CMUT according to another example embodiment;

FIG. 7 is an enlarged view of a portion B of FIG. 6;

FIGS. 8A through 8E are cross-sectional views illustrating a method of fabricating the CMUT illustrated in FIG. 6 according to another example embodiment;

FIG. 9 is a schematic cross-sectional view of a CMUT according to another example embodiment;

FIG. 10 is an enlarged view of a portion D of FIG. 9; and

FIGS. 11A through 11C are cross-sectional views illustrating a method of fabricating the capacitive micromachined ultrasonic transducer illustrated in FIG. 9 according to another example embodiment.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference characters and/or numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

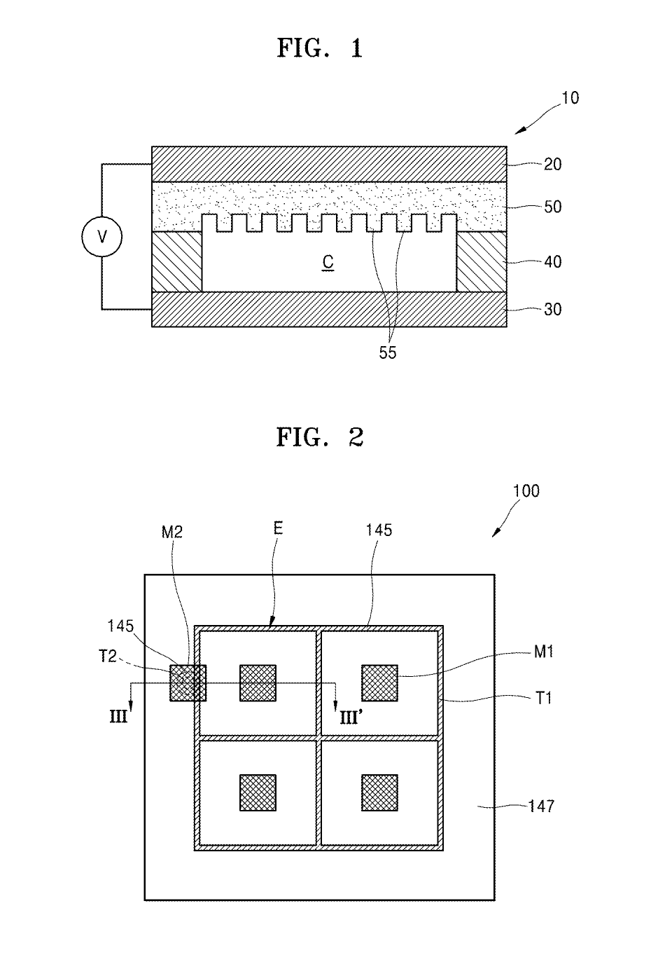

FIG. 1 is a schematic conceptual view of a structure of a capacitive micromachined ultrasonic transducer (CMUT) 10 according to an example embodiment.

FIG. 1 illustrates a driving unit that may include a cell in which one cavity C may be formed. An upper electrode 20 and a lower electrode 30 may be formed to be spaced apart from each other by a desired (and/or predetermined) distance by using a support 40. A membrane 50 may be formed at a lower portion of the upper electrode 20. A plurality of nanopillars 55 may be formed at a lower portion of the membrane 50 and may protrude toward the lower electrode 30. When a desired (and/or predetermined) pulse voltage is applied between the upper electrode 20 and the lower electrode 30, electrostatic attraction F may be generated between the upper electrode 20 and the lower electrode 30. Thus, the membrane 50 may be driven.

The electrostatic attraction F between the upper electrode 20 and the lower electrode 30 may be represented by the following Equation 1.

$$F = \frac{ɛ {AV}^{2}}{2 {d}^{2}} \qquad [ Equation 1 ]$$

In Equation 1, A denotes a surface area of the upper electrode 20, V denotes an application voltage between the upper electrode 20 and the lower electrode 30, d denotes a distance between the upper electrode 20 and the lower electrode 30, and ε denotes a permittivity.

The membrane 50 may have a conductivity. Since a nanopillar structure may be formed at the lower portion of the membrane 50, the surface area A of the upper electrode 20 that faces the lower electrode 30 may be increased. According to Equation 1, the electrostatic attraction F is increased due to an increase in the surface area A of the upper electrode 20. Also, due to formation of the nanopillar structure, a fringe effect of an electrostatic field may occur. Thus, the electrostatic attraction F is further increased.

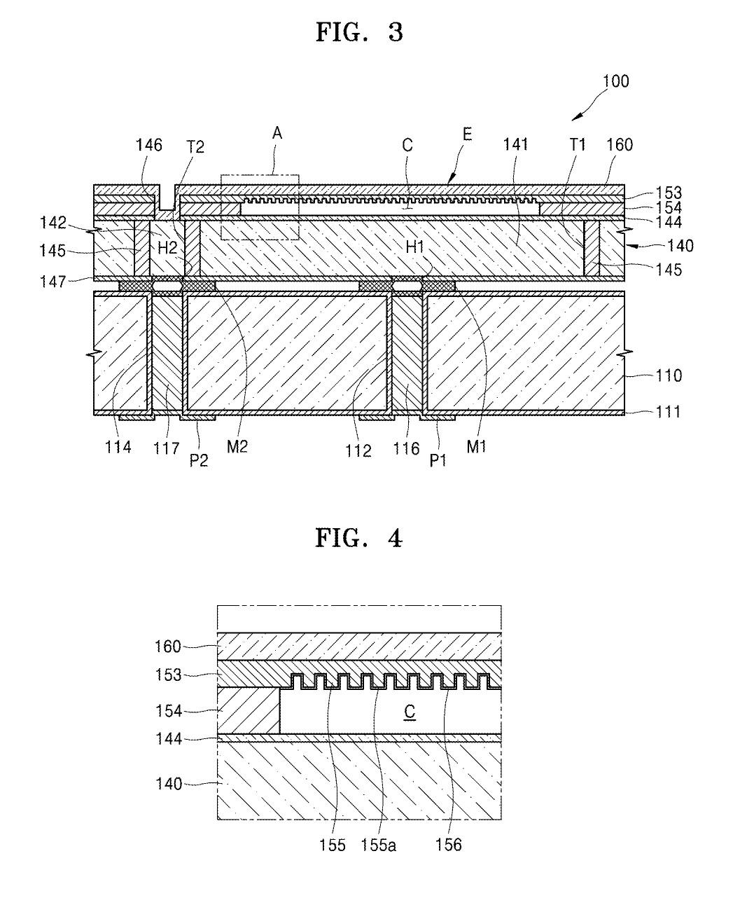

FIG. 2 is a schematic bottom view of a structure of a CMUT 100 according to an example embodiment. FIG. 3 is a cross-sectional view taken along line a III-Ill′ of FIG. 2.

Referring to FIG. 2, the CMUT 100 may include a plurality of elements E. For example, the CMUT 100 may include a plurality of elements E that are arranged in a 16×16 matrix. In FIG. 1, for convenience, only four elements E are shown, but the plurality of elements E is not limited thereto. The CMUT 100 may be referred to as an ultrasonic transducer chip.

A first trench T1 that may be an insulating trench may be formed around the elements E so as to reduce and/or prevent crosstalk between the elements. The first trench T1 may be formed in a lattice form. A first bonding metal M1 may be formed on each of the elements E.

A second trench T2 may be formed at one side of the element E. A second bonding metal M2 may be formed to be connected to a second portion (see 142 of FIG. 3) surrounded by the second trench T2. The second trench T2 may also be formed to be connected to the first trench T1, as illustrated in FIG. 2.

Referring to FIG. 3, the CMUT 100 may include a “through-silicon via” (TSV) substrate 110 and a device substrate 140 bonded to the TSV substrate 110. The device substrate 140 may be bonded onto the TSV substrate 110. The TSV substrate 110 and the device substrate 140 may be bonded to each other through eutectic bonding.

The TSV substrate 110 may include a silicon substrate and may have a plurality of through holes 112 formed in the TSV substrate 110. The plurality of through holes 112 corresponding to the plurality of elements E and a through hole 114 for a upper electrode may be formed in each CMUT 100. An insulating layer 111 may be formed on a surface of the through holes 112 and 114 and the TSV substrate 110, and a first via metal 116 may be filled in the through hole 112, and a second via metal 117 may be filled in the through hole 114.

The first trench T1 may have the lattice shape to define the plurality of elements E and the second trench T2 for the upper electrode may be formed in the device substrate 140. The device substrate 140 may include a first portion 141 surrounded by the first trench T1 and a second portion 142 surrounded by the second trench T2.

The device substrate 140 may be formed of a conductive material, and a thickness of the device substrate 140 may be about 10 μm to about 50 μm. The device substrate 140 may include low resistivity silicon which may be highly doped with impurities.

The first portion 141 and the second portion 142 of the device substrate 140 may be conductive regions. The first portion 141 of the device substrate 140 may be used as a lower electrode.

An insulating material 145 may be filled in the first trench T1 and the second trench T2. The insulating material 145 may include silicon oxide.

The device substrate 140 may include an insulating layer 144 that may be formed on a top surface of the device substrate 140, a support 154 that may define the cavity C, and a membrane 153 that may be on the support 154 to cover the cavity C.

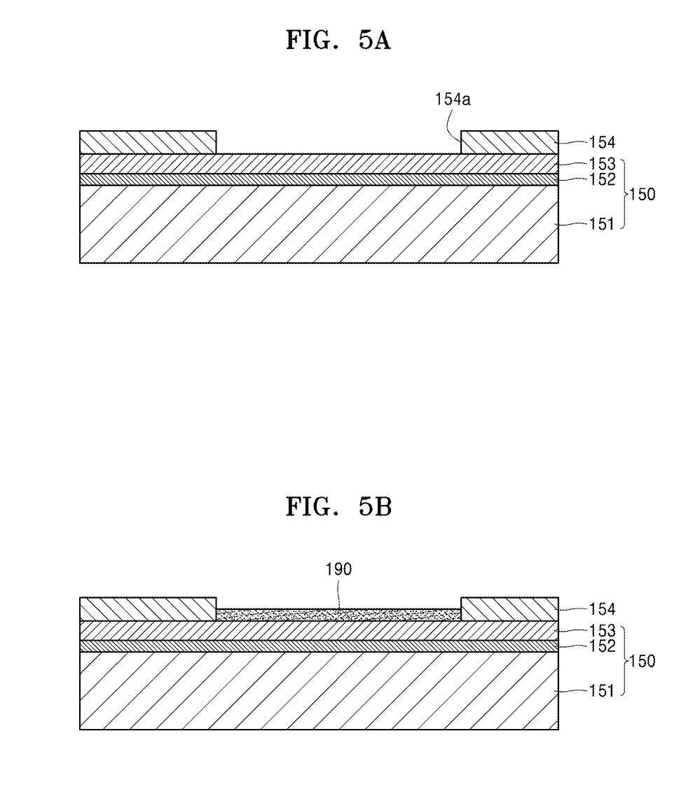

FIG. 4 is an enlarged view of a portion A of FIG. 3.

Referring to FIG. 4, the membrane 153 may include a plurality of nanopillars 155 that may be disposed at a lower portion of the membrane 153 and may be aligned in a direction toward the insulating layer 144. An insulating layer 156 may be formed on the plurality of nanopillars 155. The nanopillars 155 may be formed by etching perimeters of the nanopillars, as will be described below. Protrusion surfaces 155a of the nanopillars 155 may be on the same plane as a surface of the membrane 153 that contacts the support 154. Diameters of the nanopillars 155 may be about 10 nm to about 100 nm, but are not limited thereto. Heights of the nanopillars 155 may be about 10 nm to about 100 nm, but are not limited thereto.

The insulating layer 156 may include an oxide and a nitride, for example, a silicon oxide, or the like.

An upper electrode 160 may be formed on the membrane 153. The membrane 153 may be formed of conductive silicon. The support 154 may be formed as an insulator. The support 154 may include an oxide and a nitride, for example, a silicon oxide, or the like.

The upper electrode 160 may be formed of Au, Cu, Sn, Ag, Al, Pt, Ti, Ni, Cr, and the like, or a mixture thereof. The insulating layer 144 may include an oxide and a nitride, for example, a silicon oxide, or the like. In FIG. 3, one cavity C may be formed on one element E. However, the example embodiments are not limited thereto. For example, a cavity having a 5×5 array cavities may be formed on one element E.

A via hole 146 may be formed in the membrane 153, the support 154, and the insulating layer 144 by penetrating through and exposing the second portion 142 of the device substrate 140 surrounded by the second trench T2. The upper electrode 160 may be electrically connected to the second portion 142 of the device substrate 140 by covering the via hole 146.

An insulating layer 147 may be formed on a lower portion of the device substrate 140. A first hole H1 through which the first portion 141 of the device substrate 140 may be exposed, and a second hole H2 through which the second portion 142 of the device substrate 140 may be exposed, are formed in the insulating layer 147. The first hole H1 may be formed at a position corresponding to the first via metal 116, and the second hole H2 may be formed at a position corresponding to the second via metal 117.

The first bonding metal M1 connected to the first portion 141 may be formed in the first hole H1, and the second bonding metal M2 connected to the second portion 142 may be formed in the second hole H2. The first bonding metal M1 may be connected to the first via metal 116 in the through holes 112, and the second bonding metal M2 may be connected to the second via metal 117 in the through holes 114. The first bonding metal M1 and the second bonding metal M2 may be formed when eutectic bonding metals formed in corresponding portions between the device substrate 140 and the TSV substrate 110 are eutectic bonded.

A first electrode pad P1 connected to the first via metal 116 and a second electrode pad P2 connected to the second via metal 117 may be formed on a lower portion of the TSV substrate 110. A ground voltage may be applied to the second electrode pad P2, and a driving signal voltage may be applied to the first electrode pad P1.

The driving signal voltage applied to the first electrode pad P1 may be supplied to the first portion 141 that may be a lower electrode, via the first via metal 116 and the first bonding metal M1.

The ground voltage applied to the second electrode pad P2 may be supplied to the upper electrode 160 via the second via metal 167, the second bonding metal M2, and the second portion 142. The CMUT 100 according to the example embodiment may include a membrane having nanopillars. Thus, electrostatic attraction between the upper electrode 160 and the lower electrode 141 may be increased at the same driving voltage. Also, the driving voltage of the CMUT 100 may be decreased.

Hereinafter, a method of fabricating the CMUT according to an example embodiment will be described.

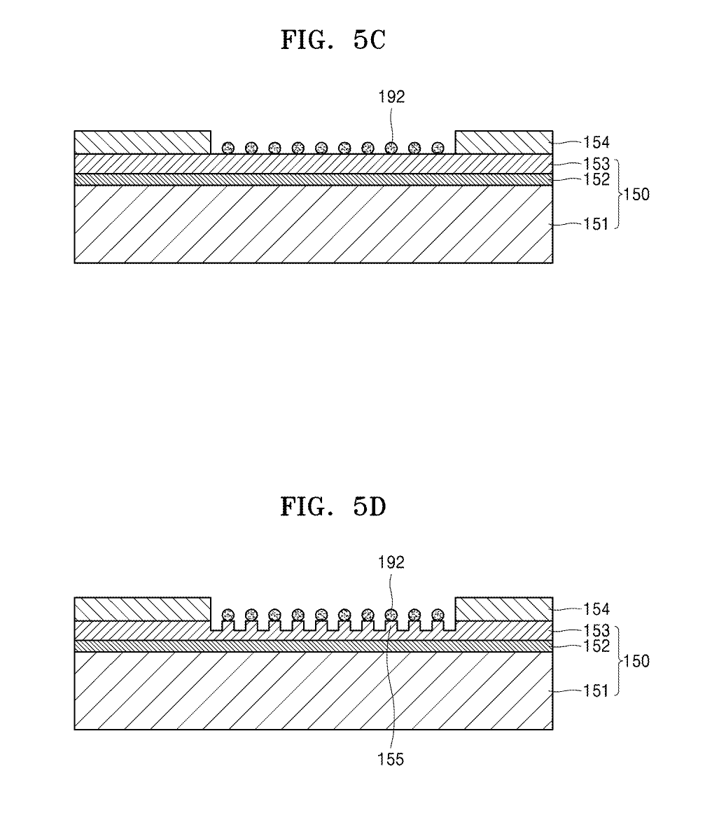

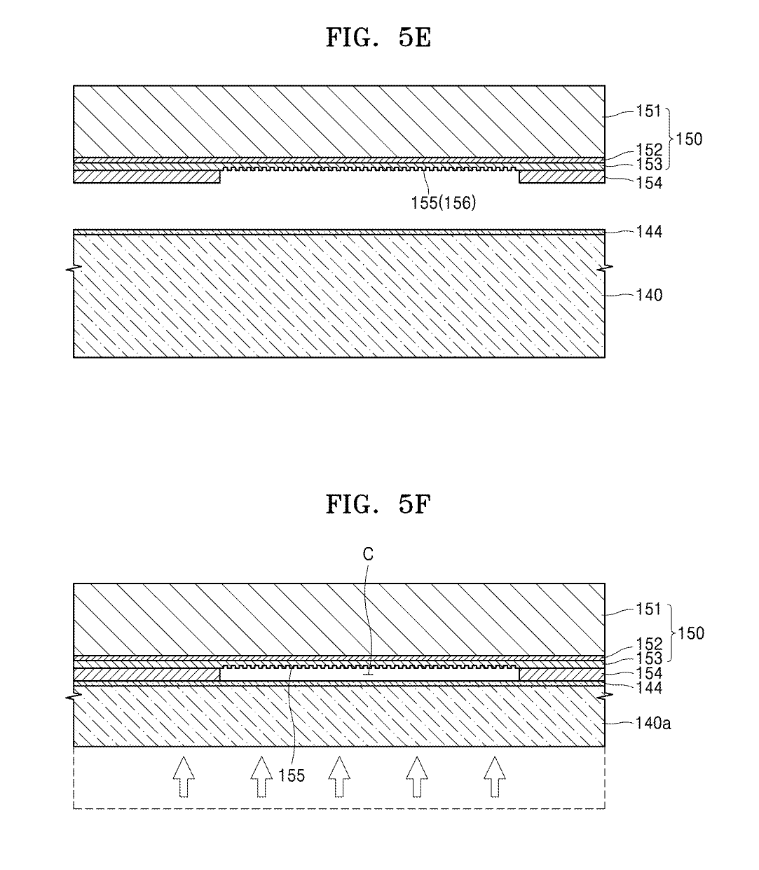

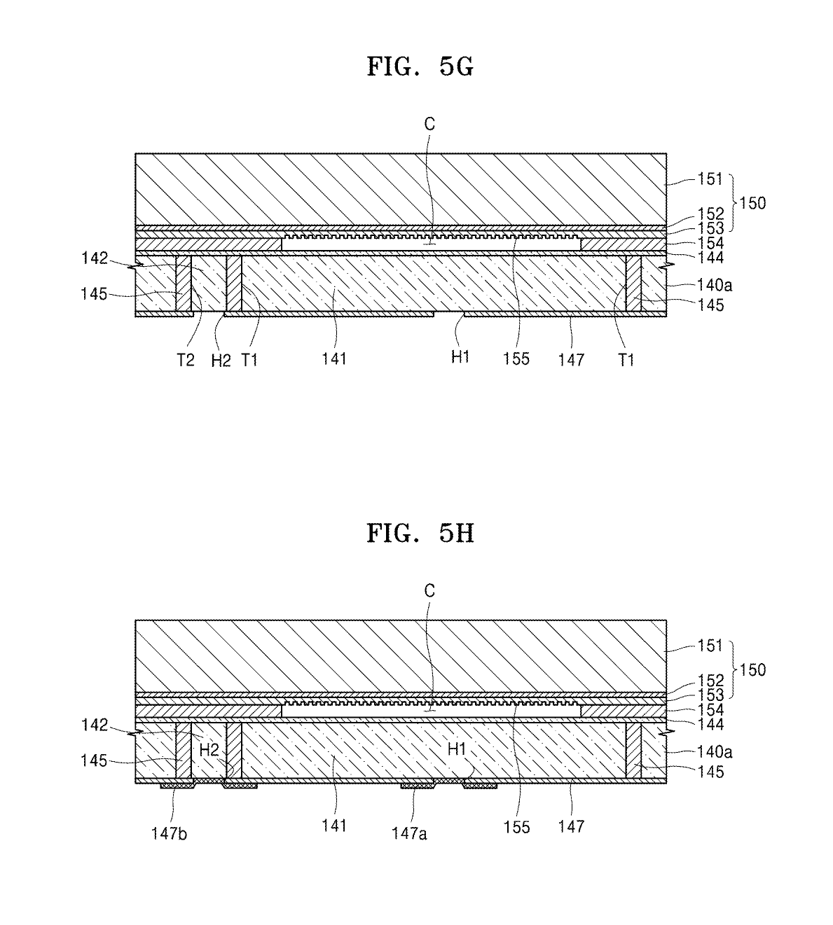

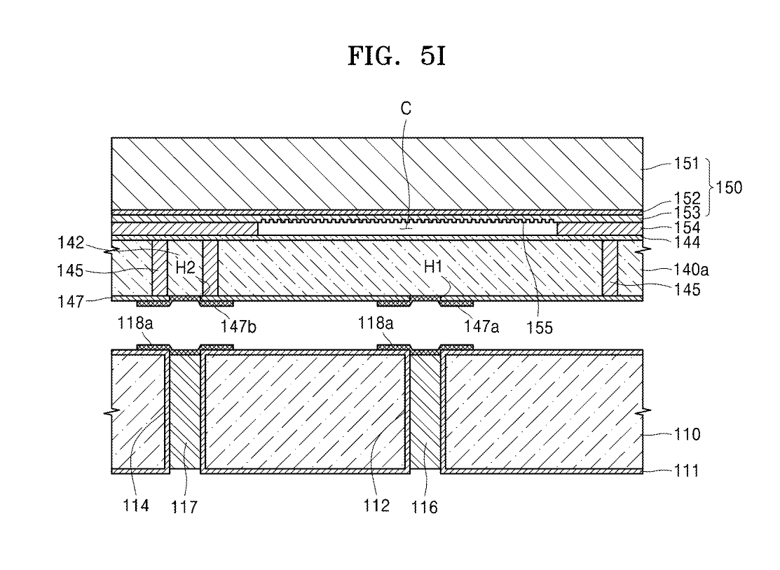

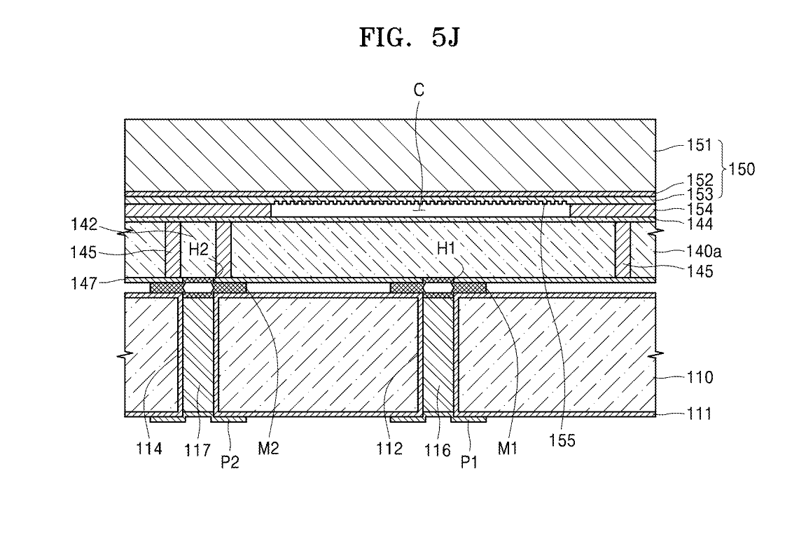

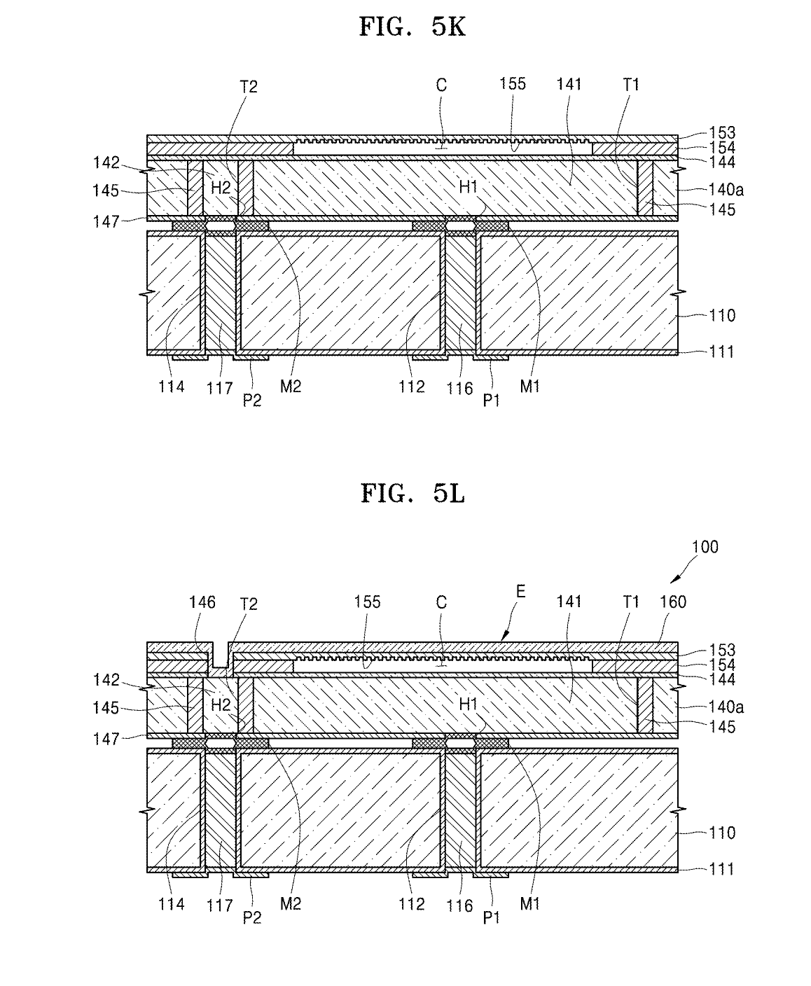

FIGS. 5A through 5L are cross-sectional views illustrating a method of fabricating the CMUT 100 according to an example embodiment. FIGS. 5A through 5L are illustrated based on the cross-sectional view taken along a line III-Ill′ of FIG. 2. Like reference numerals are used for like elements having substantially the same structures as those of FIG. 3, and thus, a detailed description thereof will be omitted here.

Referring to FIG. 5A, after a first insulating layer 154 is formed on a first substrate 150, the first insulating layer 154 may be patterned so that an opening 154a may be formed. The first substrate 150 may be a “silicon on insulator” (SOI) substrate. The SOI substrate 150 may include a first silicon layer 151, a buried oxide layer 152, and a second silicon layer 153, which may be sequentially stacked in this order. The second silicon layer 153 that corresponds to the membrane 153 of FIG. 3 may be formed to have a thickness of about 200 nm, but is not limited thereto.

The first insulating layer 154 may be formed of a silicon oxide and may be formed by oxidizing the first substrate 150, but other types of insulators may be used as well. The patterned first insulating layer 154 may correspond to the support 154 of FIG. 3. A height of the opening 154a may be determined by a thickness of the first insulating layer 154. The thickness of the first insulating layer 154 may be about 400 mm.

Referring to FIG. 5B, a metal layer 190 may be deposited on the second silicon layer 153. The metal layer 190 may be formed of silver (Ag) having a thickness of about 10 nm to about 50 nm. The metal layer 190 may be formed only in the opening 154a using a patterning process.

Referring to FIG. 5C, a plurality of metal balls 192 may be formed on the second silicon layer 153 by annealing the metal layer 190. For example, when the metal layer 190 is formed of Ag, the metal layer 190 may be annealed at about 400° C. to about 1000° C. for about 5 to about 10 minutes, but is not limited thereto. The annealing process may be performed based on a material for the metal layer 190. In the annealing process, the metal layer 190 may be agglomerated to form the plurality of metal balls 192 having an approximately spherical shape. Sizes (diameters) of the metal balls 192 may be about 10 nm to about 100 nm, but is not limited thereto, and a distance between the metal balls 192 may be about 10 nm to about 100 nm, but is not limited thereto.

Referring to FIG. 5D, the second silicon layer 153 may be dry etched using the metal balls 192 as an etching mask. A plurality of nanopillars 155 protruding upwards may be formed on the second silicon layer 153. The plurality of nanopillars 155 may have diameters of about 10 nm to about 100 nm, but is not limited thereto, and heights of the nanopillars 155 may be about 10 nm to about 100 nm, but is not limited thereto.

When the patterning process using the metal balls 192 is completed, the metal balls 192 may be removed. The metal balls 192 may be removed by wet etching.

Referring to FIG. 5E, the second insulating layer (see 156 of FIG. 4) that covers the nanopillars 155 may be formed on the second silicon layer 153. The second insulating layer 156 may be formed on the surface of the nanopillars 155 by thermally oxidizing the nanopillars 155.

A third insulating layer 144 may be formed on the device substrate 140. The first substrate 150 may be bonded to the device substrate 140 so that the first insulating layer 154 and the third insulating layer 144 face each other. The device substrate 140 may be formed of a low resistivity silicon, or another low resistivity semiconducting material. The third insulating layer 144 may be formed of a silicon oxide, or the like, that is formed by thermally oxidizing the device substrate 140.

Referring to FIG. 5F, the first substrate 150 and the device substrate 140 may be wafer-to-wafer bonded to each other by using a silicon direct bonding (SDB) process. The first substrate 150 and the device substrate 140 may be bonded to each other so that a cavity C that is a sealed space may be formed.

The device substrate 140 may be thinned so that a device substrate 140a having a thickness of about 10 μm to about 50 μm may be formed, but is not limited thereto. In order to perform the thinning process, first, the device substrate 140 may be mechanically lapped and then, a chemical-mechanical polishing (CMP) process may be performed. A trench may be easily formed in the device substrate 140a due to the thinning process.

Referring to FIG. 5G, a first trench T1 and a second trench T2 may be formed in the device substrate 140a. The first trench T1 may be formed to surround a first portion 141 of the device substrate 140a so that a plurality of elements E of each chip may be divided from one another. The first trench T1 may be formed in a lattice form, as illustrated in FIG. 2. The second trench T2 may be formed to surround a second portion 142 of the device substrate 140a.

The first trench T1 and the second trench T2 may be formed to penetrate the device substrate 140a. The first trench T1 and the second trench T2 may have the same, or different, widths. When the first trench T1 and the second trench T2 have the same widths, the first trench T1 and the second trench T2 may be formed using one mask. In the related art, a width of a trench (which corresponds to the first trench T) for dividing the elements E and a width of a via for connecting an upper electrode are different from each other so that an etching time for the trench for dividing the elements E and an etching time for the via for connecting the upper electrode are different from each other. Thus, the trench for dividing the elements E and the via for connecting the upper electrode are formed using a separate etching process. However, in the example embodiment, the first trench T1 and the second trench T2 may be simultaneously formed.

Each of the first trench T1 and the second trench T2 may be formed to have a width of about 1 μm to about 10 μm, but they are not limited thereto. When widths of the first trench T1 and the second trench T2 are less than 1 μm, aspect ratios of cross-sections of the first trench T1 and the second trench T2 are large so that it is not easy to perform an etching process of the first trench T1 and the second trench T2. When the widths of the first trench T1 and the second trench T2 are greater than about 10 μm, frequency characteristics of the capacitive micromachined ultrasonic transducer may be deteriorated.

Subsequently, the device substrate 140a may be thermally oxidized so that the first trench T1 and the second trench T2 may be filled with a silicon oxide 145. Also, a fourth insulating layer 147 may be formed on a bottom surface of the device substrate 140a. The first trench T1 and the second trench T2 do not need to be fully filled with the silicon oxide.

The fourth insulating layer 147 may be patterned so that a first hole H1 through which the first portion 141 may be exposed and a second hole H2 through which the second portion 142 surrounded by the second trench T2 may be exposed, may be formed. The first portion 141 may be a region that corresponds to one element E.

Referring to FIG. 5H, after a metal layer is deposited on the bottom surface of the device substrate 140a to cover the fourth insulating layer 147, the metal layer may be patterned so that a first bonding pad 147a and a second bonding pad 147b may be formed to cover the first hole H1 and the second hole H2. The first bonding pad 147a and the second bonding pad 147b may be formed of materials for eutectic bonding. For example, the first bonding pad 147a and the second bonding pad 147b may be formed of gold (Au) and/or tin (Sn) for Au—Sn eutectic bonding.

Referring to FIG. 5I, a TSV substrate 110 may be prepared. A first through hole 112 and a second through hole 114 are formed in the TSV substrate 110. The first through hole 112 and the second through hole 114 may be formed to have widths of approximately several tens of μm. The first through hole 112 may be formed to correspond to the first portion 141, and the second through hole 114 may be formed to correspond to the second portion 142.

A fourth insulating layer 111 may be formed on the TSV substrate 110. The fourth insulating layer 111 may be formed by oxidizing the TSV substrate 110. The fourth insulating layer 111 may be formed on surfaces of the first through hole 112 and the second through hole 114 and top and bottom surfaces of the TSV substrate 110. The first through hole 112 and the second through hole 114 may be filled with metals respectively so that a first via metal 116 and a second via metal 117 may be formed.

After a metal layer may be formed on the TSV substrate 110, the metal layer may be patterned so that a third bonding pad 118a and a fourth bonding pad 118b may be formed. The third bonding pad 118a may be formed on the first via metal 116 so as to correspond to the first bonding pad 147a, and the fourth bonding pad 118b may be formed on the second via metal 117 so as to correspond to the second bonding pad 147b.

The third bonding pad 118a and the fourth bonding pad 118b may be formed of eutectic bonding metals. For example, the third bonding pad 118a and the fourth bonding pad 118b may be formed of Au and/or Sn for Au—Sn eutectic bonding.

Referring to FIG. 5J, the TSV substrate 110 and the device substrate 140a are bonded to each other. For example, the TSV substrate 110 and the device substrate 140a are eutectic-bonded to each other. Eutectic bonding may be performed by Au/Sn bonding, for example. In this case, the first bonding pad 147a and the third bonding pad 118a are coupled to each other so that a first bonding metal M1 may be formed, and the second bonding pad 147b and the fourth bonding pad 118b are coupled to each other so that a second bonding metal M2 may be formed.

A first electrode pad P1 connected to the first via metal 116 and a second electrode pad P2 connected to the second via metal 117 are formed on the bottom surface of the TSV substrate 110.

Referring to FIG. 5K, the first silicon layer 151 and the buried oxide layer 152 may be sequentially removed from the first substrate 150. After the first silicon layer 151 is firstly removed by mechanical lapping, a remaining portion of the first silicon layer 151 having a thickness of several tens of μm may be removed by dry etching. The buried oxide layer 152 may be removed by wet etching.

Referring to FIG. 5L, a via hole 146 may be formed in the second silicon layer 153, the first insulating layer 154, and the second insulating layer 144 so that the second portion 142 may be exposed through the via hole 146. An upper electrode 160 may be formed on the second silicon layer 153. The upper electrode 160 may be formed to be electrically connected to the second portion 142 by covering the via hole 146.

The structure fabricated in the above-described processes may be diced into chips so that a plurality of CMUT chips 100 may be fabricated.

According to some example embodiments, pillars having nano sizes may be formed on a membrane by using the metal balls, which are agglomerated by thermal treatment, as a mask.

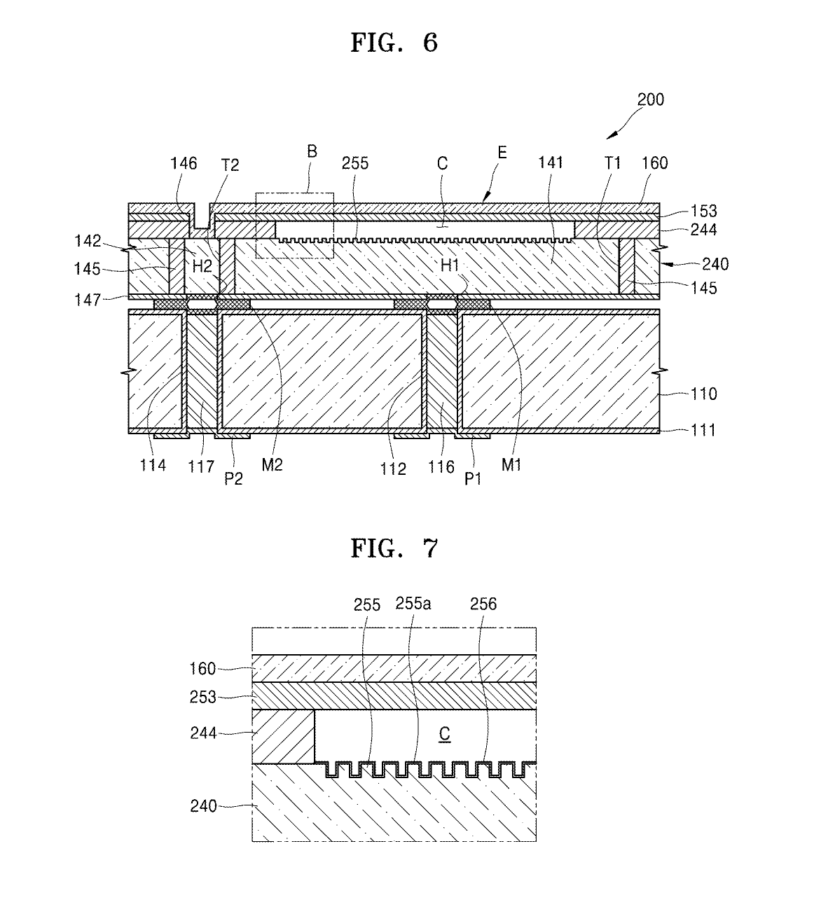

FIG. 6 is a schematic cross-sectional view of a CMUT 200 according to another example embodiment. FIG. 7 is an enlarged view of a portion B of FIG. 6. Like reference numerals are used for like elements having substantially the same structures as those stated above, and thus, a detailed description thereof will be omitted here.

Referring to FIGS. 6 and 7, a plurality of nanopillars 255 may be formed on a device substrate 240. The plurality of nanopillars 255 may be formed by etching a surface of the device substrate 240. A fourth insulating layer 256 may be formed on surfaces of the nanopillars 255. Protrusion surfaces 255a of the nanopillars 255 may be on the same plane as a top surface of the device substrate 240 that contacts a support 244.

Diameters of the nanopillars 255 may be about 10 nm to about 100 nm, but are not limited thereto. Heights of the nanopillars 255 may be about 10 nm to about 100 nm, but are not limited thereto.

The CMUT 200 having a nanopillar structure according to an example embodiment is different from the CMUT 100 of FIG. 2 in that the nanopillar structure of the CMUT 200 may be formed on a top surface of the device substrate that is a lower electrode. However, a function of the CMUT 200 is the same as that of the CMUT 100 and thus, a detailed description thereof will be omitted here.

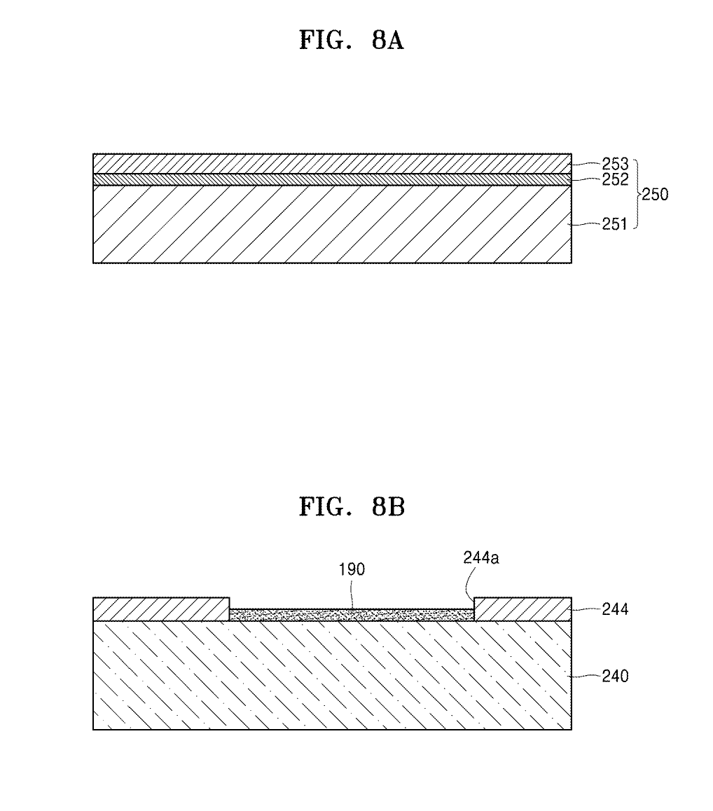

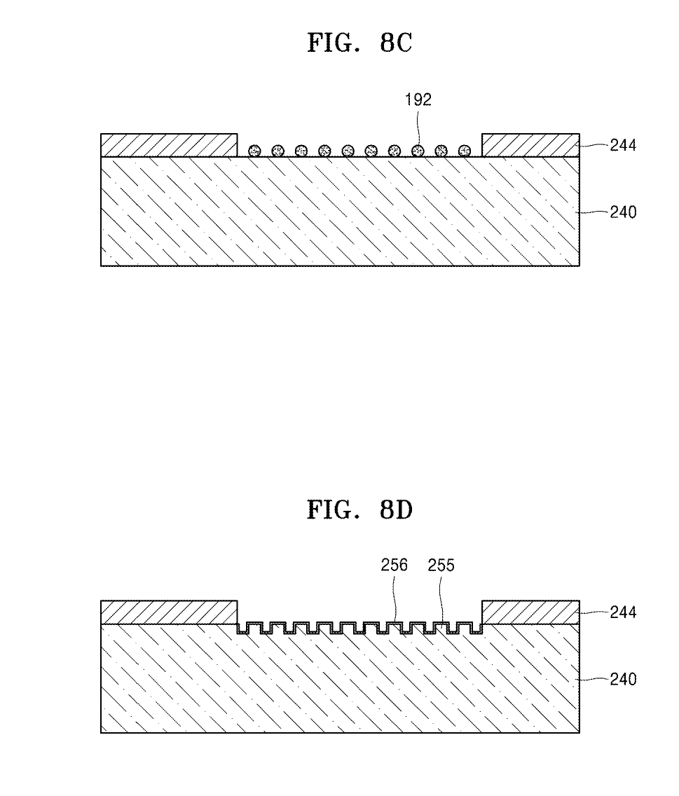

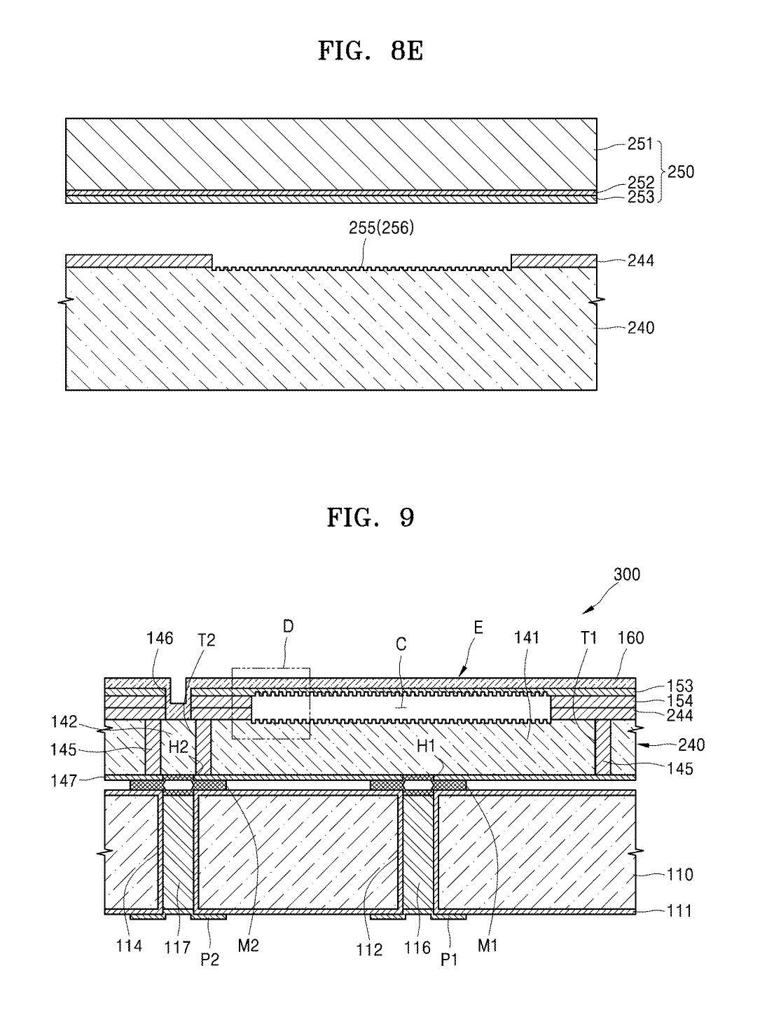

FIGS. 8A through 8E are cross-sectional views illustrating a method of fabricating the CMUT of FIG. 6 according to another example embodiment. Like reference numerals are used for like elements having substantially the same structures as those of FIG. 6, and thus, a detailed description thereof will be omitted here.

Referring to FIG. 8A, a first substrate 250 may be prepared. The first substrate 250 may be an SOI substrate, but is not limited thereto. The SOI substrate 250 may include a first silicon layer 251, a buried oxide layer 252, and a second silicon layer 253, which may be sequentially stacked in this order. The second silicon layer 253 that corresponds to the membrane 253 of FIG. 6 may be formed to a thickness of about 200 nm, but is not limited thereto.

Referring to FIG. 8B, after a first insulating layer 244 may be formed on the device substrate 240, the first insulating layer 244 may be patterned so that an opening 244a may be formed.

The first insulating layer 244 may be formed of a silicon oxide, or another insulator material, and may be formed by oxidizing the device substrate 240. The patterned first insulating layer 244 corresponds to the support 244 of FIG. 6. A height of the opening 244a may be determined by a thickness of the first insulating layer 244. The thickness of the first insulating layer 244 may be about 400 nm, but is not limited thereto.

After a metal layer is deposited onto the device substrate 240, a metal layer 260 may be formed only in the opening 244a by using a patterning process. The metal layer 260 may be formed of Ag having a thickness of about 10 nm to about 50 nm, but is not limited thereto.

Referring to FIG. 8C, the metal layer 260 may be annealed so that a plurality of metal balls 262 may be formed on the device substrate 240. For example, when the metal layer 260 is formed of Ag, the metal layer 260 may be annealed at about 400° C. to about 1000° C. for about 10 minutes, but are not limited thereto. In the annealing process, the metal layer 260 may be agglomerated to form metal balls 262 having an approximately spherical shape. Sizes (diameters) of the metal balls 262 may be about 10 nm to 100 nm, but are not limited thereto, and a distance between the metal balls 262 may be about 10 nm to about 100 nm, but are not limited thereto.

Referring to FIG. 8D, the device substrate 240 may be dry etched using the metal balls 262 as an etching mask. A plurality of nanopillars 255 protruding upwards may be formed on the device substrate 240. The plurality of nanopillars 255 may have diameters of about 10 nm to about 100 nm, but are not limited thereto, and heights of the nanopillars 255 may be about 10 nm to about 100 nm, but are not limited thereto.

When the patterning process using the metal balls 262 is completed, the metal balls 262 may be removed. The metal balls 262 may be removed by wet etching.

A second insulating layer 256 that covers the nanopillars 255 may be formed on the device substrate 240. The nanopillars 255 may be oxidized so that the second insulating layer 256 may be formed on surfaces of the nanopillars 255.

Referring to FIG. 8E, the SOI substrate 250 may be bonded to the device substrate 240 so that the second silicon layer 253 and the nanopillars 255 may face each other. The device substrate 240 may be formed of low resistivity silicon, or the like.

Following process may be apparent from the above-described example embodiments and thus, a detailed description thereof will be omitted here.

According to an example embodiment, pillars having nano sizes may be formed by patterning the device substrate.

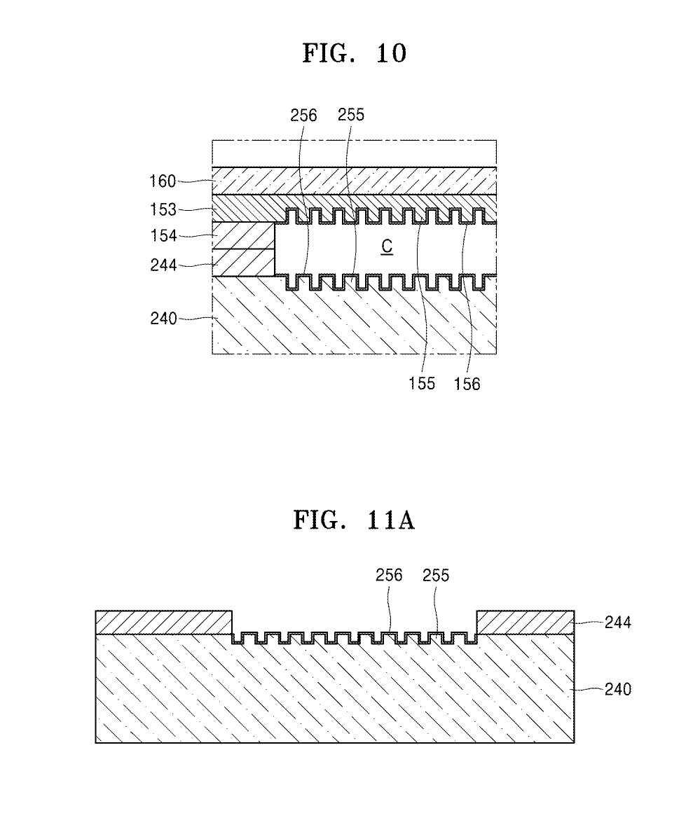

FIG. 9 is a schematic cross-sectional view of a CMUT 300 according to another example embodiment. FIG. 10 is an enlarged view of a portion D of FIG. 9. Like reference numerals are used for like elements having substantially the same structures as those of FIGS. 3 and 6, and thus, a detailed description thereof will be omitted here.

Referring to FIGS. 9 and 10, a first support 244 that defines a cavity C may be formed on a device substrate 240. A second support 154 that corresponds to the first support 244 may be formed on a membrane 153.

A plurality of first nanopillars 255 may be formed on a surface of the device substrate 240 exposed to the cavity C, and a plurality of second nanopillars 155 may be formed on a surface of the membrane 153 exposed to the cavity C. An insulating layer 256 may be formed on the plurality of first nanopillars 255. An insulating layer 156 may be formed on the second nanopillars 155. The insulating layer 256 and the insulating layer 156 may be formed by oxidizing the first nanopillars 255 and the membrane 153, respectively.

The other elements may be apparent from FIGS. 3, 4, 6, and 7 and thus, a detailed description thereof will be omitted here.

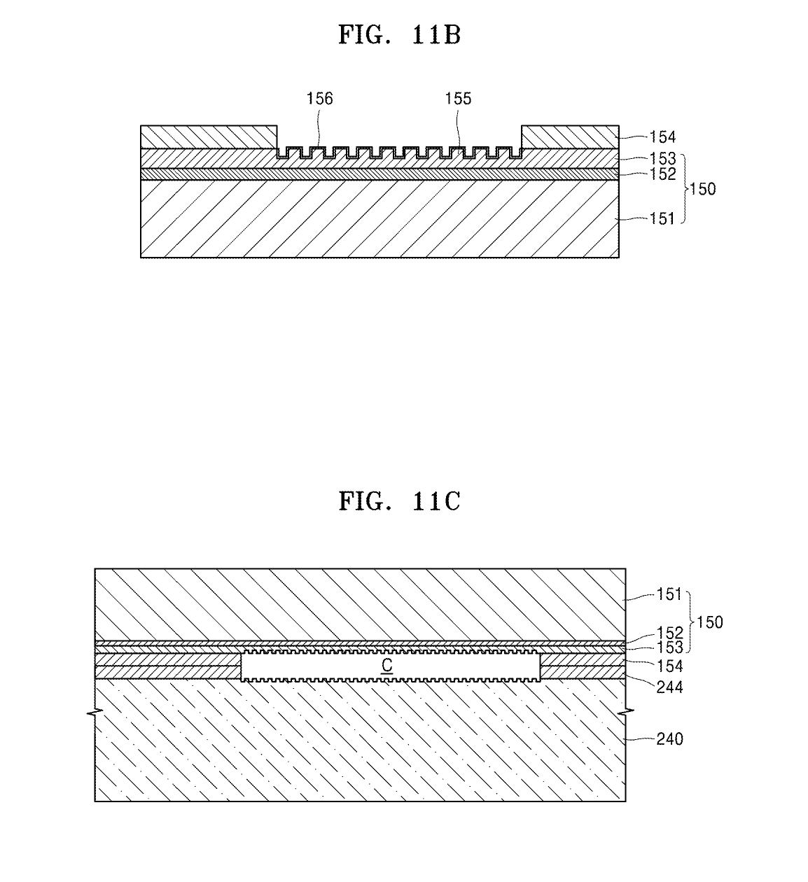

FIGS. 11A through 11C are cross-sectional views illustrating a method of fabricating the CMUT 300 of FIG. 9 according to another example embodiment. Like reference numerals are used for like elements having substantially the same structures as those of FIGS. 3 and 6, and thus, a detailed description thereof will be omitted here.

Referring to FIG. 11A, after an insulating layer 244 is formed on a device substrate 240, the insulating layer 244 may be patterned so that an opening 244a may be formed thereon. The opening 244a may define a cavity region. The patterned insulating layer 244 corresponds to the first support 244 of FIG. 9.

A plurality of first nanopillars 255 may be formed on a surface of the device substrate 240 exposed by the insulating layer 244, and an insulating layer 256 may be formed on the plurality of first nanopillars 255. This process may be well-known from the description relating to FIGS. 8A through 8D and thus, a detailed description thereof will be omitted.

Referring to FIG. 11B, a first substrate 150 may be prepared. The first substrate 150 may be an SOI substrate. The SOI substrate 150 may include a first silicon layer 151, a buried oxide layer 152, and a second silicon layer 153, which may be sequentially stacked in this order. The second silicon layer 153 corresponds to the membrane 153 of FIG. 9.

After the insulating layer 154 is formed on the first insulating layer 150, the insulating layer 154 may be patterned so that an opening 154a that defines the cavity region may be formed. The patterned insulating layer 154 corresponds to the second support 154 of FIG. 9.

A plurality of second nanopillars 155 may be formed on a surface of the second silicon layer 153 exposed by the insulating layer 244, and an insulating layer 156 may be formed on the plurality of second nanopillars 155. This process may be apparent from the description relating to FIGS. 5A through 5D and thus, a detailed description thereof will be omitted here.

Referring to FIG. 11C, the first substrate 150 may be bonded to the device substrate 240 when the second support 154 of the first substrate 150 may face the first support 244 of the device substrate 240.

Following process may be apparent from the above-described example embodiments and thus, a detailed description thereof will be omitted here.

As described above, according to one or more of the above example embodiments, the CMUT 300 may have the nanopillar structure formed on a top surface of the device substrate that is a lower electrode and a surface of a membrane, respectively, so that electrostatic attraction may be increased.

Since the capacitive micromachined ultrasonic transducer according to one or more example embodiments includes nanopillars connected to an electrode of a driving unit, the electrostatic attraction may be increased. Thus, the size of the driving unit of the capacitive micromachined ultrasonic transducer may be decreased, and power consumption may be reduced.

In the method of fabricating the capacitive micromachined ultrasonic transducer having the nanopillar structure according to one or more example embodiments, nanosized fine patterns may be easily formed on a surface of an electrode of the driving unit by using agglomeration of metal.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims

What is claimed is:

1. A capacitive micromachined ultrasonic transducer (CMUT) comprising:
a conductive device substrate;
a support defining a plurality of cavities corresponding to a plurality of elements on the device substrate;
a membrane on the support to form the plurality of cavities;
an upper electrode on the membrane; and
a plurality of nanopillars on at least one of the membrane and the device substrate, exposed to the plurality of cavities.

2. The CMUT of claim 1, wherein the plurality of nanopillars are on a surface of the membrane protruding toward the device substrate.

3. The CMUT of claim 2, wherein protrusion surfaces of the plurality of nanopillars are on a same plane as the surface of the membrane contacting the support.

4. The CMUT of claim 2, wherein diameters of the plurality of nanopillars are in a range from 10 nm to 100 nm.

5. The CMUT of claim 2, further including an insulating layer on an exposed surface of the plurality of nanopillars.

6. The CMUT of claim 1, wherein the plurality of nanopillars are on a surface of the device substrate protruding toward the membrane.

7. The CMUT of claim 6, wherein protrusion surfaces of the plurality of nanopillars are on a same plane as the surface of the device substrate contacting the support.

8. The CMUT of claim 6, wherein diameters of the plurality of nanopillars are in a range from 10 nm to 100 nm.

9. The CMUT of claim 6, further including an insulating layer on an exposed surface of the plurality of nanopillars.

10. The CMUT of claim 1, wherein the plurality of nanopillars include:
a plurality of first nanopillars on a surface of the membrane protruding toward the device substrate; and
a plurality of second nanopillars on a surface of the device substrate protruding toward the membrane.

11. The CMUT of claim 10, wherein protrusion surfaces of the plurality of first nanopillars are on a same plane as the surface of the membrane contacting the support, and
protrusion surfaces of the plurality of second nanopillars are on a same plane as the surface of the device substrate contacting the support.

12. A method of fabricating a capacitive micromachined ultrasonic transducer (CMUT), the method comprising:
forming an insulating support defining a cavity on a first substrate which is one of a device substrate and a silicon on insulator (SOI) substrate;
forming a metal layer on a surface of the first substrate exposed by the support;
agglomerating the metal layer into a plurality of metal balls by annealing the metal layer;
forming a plurality of nanopillars on the surface of the first substrate by etching the surface of the first substrate by using the plurality of metal balls as a mask;
removing the metal balls;
forming the cavity between the SOI substrate and the device substrate by bonding the SOI substrate onto the device substrate;
removing one silicon layer and a buried oxide layer of the SOI substrate sequentially so as to leave a second silicon layer of the SOI substrate on the support; and
forming an upper electrode on the second silicon layer.

13. The method of claim 12, wherein the forming of the metal layer includes forming a metal layer having a thickness of 5 nm to 50 nm on the first substrate.

14. The method of claim 12, wherein diameters of the plurality of nanopillars are in a range from 10 nm to 100 nm.

15. The method of claim 12, wherein the device substrate comprises low resistivity silicon.

16. The method of claim 12, further including forming an insulating layer that covers the plurality of nanopillars.

17. A method of fabricating a capacitive micromachined ultrasonic transducer (CMUT), the method comprising:
forming a first support on a device substrate to define a cavity;
forming a first metal layer on a surface of the device substrate exposed by the support;
forming a plurality of first metal balls on the surface of the device substrate by annealing the first metal layer;
forming a plurality of first nanopillars on the surface of the device substrate by etching the surface of the device substrate by using the plurality of metal balls as a mask;
removing the metal balls;
forming a second support corresponding to the first support on a silicon on insulator (SOI) substrate;
forming a second metal layer on a surface of the SOI substrate exposed by the second support;
forming a plurality of second metal balls on the surface of the SOI substrate by annealing the second metal layer;
forming a plurality of second nanopillars on the surface of the SOI substrate by etching the surface of the SOI substrate by using the plurality of second metal balls as a mask;
forming the cavity between the SOI substrate and the device substrate by bonding the SOI substrate onto the device substrate so that the first support and the second support overlap each other;
removing one silicon layer and a buried oxide layer of the SOI substrate sequentially so as to leave a second silicon layer of the SOI substrate on the second support; and
forming an upper electrode on the second silicon layer.

18. The method of claim 17, wherein the forming of the first metal layer and the second metal layer includes forming a metal layer having a thickness of 5 nm to 50 nm on respective substrates.

19. The method of claim 17, wherein diameters of each of the plurality of first nanopillars and the plurality of second nanopillars are in a range from 10 nm to 100 nm.

20. The method of claim 17, further including forming an insulating layer that covers at least one of the plurality of first nanopillars and the plurality of second nanopillars.
